(19) United States
(12) Patent Application Publication
(10) Pub. No.: US 2023/0251126 A1
(43) Pub. Date: Aug. 10, 2023

(54) System For Measuring Reduction In Weight Of Food Waste

(71) Applicant: GL Plus Co., Ltd., Bucheon-si (KR)

(72) Inventor: Sam Hyun Ko, Incheon (KR)

(21) Appl. No.: 17/699,145

(22) Filed: Mar. 20, 2022

(30) Foreign Application Priority Data
Feb. 10, 2022 (KR) 10-2022-0017361

(51) Int. Cl. G01G 23/37; G01R 19/25; H04W 4/38; B09B 3/00

(52) U.S. Cl. CPC G01G 23/3728; G01R 19/2513; H04W 4/38; B09B 3/00; B09B 2101/70

(57) ABSTRACT

Proposed is a system for measuring a reduction in a weight of food waste, the system including a food waste disposal apparatus measuring a weight of food waste introduced and a reduction in the weight of the food waste and an amount of electric power consumed, a GL server collecting data on the reduction in the weight of the food waste and data on the amount of the consumed electric power and accumulating the collected data, and computing a total of reductions in the weight of the food waste and a total of amounts of the consumed electric power on the basis of the accumulated data on the reduction in the weight of the food waste and the accumulated data on the amount of the consumed electric power, and a public office server receiving the total of reductions and the total of amounts from the GL server.

### CROSS-REFERENCE TO RELATED APPLICATIONS

This application claims priority under 35 U.S.C. § 119(a)-(d) to Korean Patent Application No. 10-2022-0017361, filed Feb. 10, 2022 the entire contents of which is incorporated herein by reference for all purposes.

### BACKGROUND OF THE INVENTION

### Field of the Invention

The present disclosure relates to a system for measuring a reduction in a weight of food and, more particularly, to a system for measuring a reduction in a weight of food waste, the system capable of measuring a weight of food waste introduced into a food disposal apparatus and a reduction in a weight of food waste and automatically providing an amount of food waste removed. With this system, a reduction in carbon emissions can be realized.

### Description of Related Art

Unless otherwise described throughout the present specification, a matter described under this heading is not prior art against the claims in this application, and inclusion of the description of the matter under this heading does not constitute an admission of prior art.

Carbon neutrality is the concept of maximally reducing an amount of greenhouse gas emissions caused by human activities and removing the remaining greenhouse gas by absorption thereof (for example, by absorption thereof by a forest and the like). That is, an amount of carbon discharged and an amount of carbon absorbed become the same, resulting in “a net amount of carbon emission being zero”. Accordingly, carbon neutrality is referred to as net-zero.

Due to global warming, abnormal weather phenomena, such as a heatwave, heavy snow, a hurricane, and a forest fire, occurs all over the world. South Korea, which depends heavily on fossil fuels and has a manufacturing-centric industrial structure, has also experienced a growing warming trends with an average temperature rising by 1.4° C. in the last 30 years. In order to solve severe problems of climate change, the Kyoto Protocol was adopted (in 1997) and it placed the obligation to reduce current emissions on developed countries. The “Paris Climate Agreement” on which developed countries and developing countries agreed was adopted in 2015 and was effective as of Nov. 4, 2016. South Korea ratified the Paris Climate Agreement on Nov. 3, 2016.

The objective of the Paris Climate Agreement is to hold the increase in the global average temperature to well below 2° C. above pre-industrial levels and pursue efforts to limit the temperature increase to 1.5° C. above pre-industrial levels. If the temperature of the earth increases by 2° C. or above, there occur natural disasters, such as a heatwave and a cold wave, that can cause loss of life or damage property and typically leaves some economic damage in its wake. The limitation of the temperature increase to 1.5° C. reduces the risks associated with biodiversity, health, livelihoods, food security, human security, and economic growth more significantly than the limitation of the temperature increase to 2° C. In order to suppress the temperature to 1.5° C. or less, there is a need to achieve carbon neutrality, that is, a state of net-zero carbon dioxide emissions, by 2050.

Usually, carbon dioxide emissions are associated with a coal-fired power generation plant, automobile exhaust fumes, or the like. However, carbon dioxide is also produced while food is cooked by burning fossil fuels. An amount of carbon dioxide emissions varies widely depending on how hood is cooked. Carbon dioxide emissions are caused throughout the food system, during production, processing, transportation, distribution, retail and food service sales, and consumption. Food waste is also associated with carbon dioxide emissions. A large amount of carbon dioxide is produced while disposing of food waste. The food waste causes various problems around the world.

China and the United States are ranked first and second, respectively, in term of how much greenhouse gas is produced due to the food waste, and followed by South Korea. An amount of food waste amounts to 15,680 tons per day and 5.7 million tons per year. In order to reduce the amount of food waste, there is a great need to control the carbon dioxide emissions due to the food waste.

The foregoing is intended merely to aid in the understanding of the background of the present disclosure, and is not intended to mean that the present disclosure falls within the purview of the related art that is already known to those skilled in the art.

### Documents of Related Art

(Patent Document 1) Korean Patent No. 10-1009737 (Jan. 13, 2011)

(Patent Document 2) Korean Patent No. 10-1482535 (Jan. 8, 2015)

### BRIEF SUMMARY OF THE INVENTION

An objective of the present disclosure is to provide a system for measuring a reduction in a weight of food waste, the system capable of measuring a weight of food waste introduced into a food waste disposal apparatus and measuring a reduction of the weight of the food waste at fixed time interval after the weight of the food waste is measured. Another objective of the present disclosure is to provide a system for measuring a reduction in a weight of food waste, the system capable of accumulating and processing data on a measured reduction in a weight of food waste and data on a measured amount of consumed electric power, integrally storing a total of reductions in the weight of the food waste in an entire food waste disposal apparatus, and sharing the integrally stored data with a server in the Ministry of Environment of Republic of Korea and servers in other public offices of Republic of Korea.

According to an aspect of the present disclosure, there is provided a system for measuring a reduction in a weight of food waste, the system including: a food waste disposal apparatus measuring a weight of food waste introduced and measuring at fixed time intervals a reduction in the weight of the food waste and an amount of electric power consumed; a GL server collecting data on the reduction in the weight of the food waste and data on the amount of the consumed electric power from the food waste disposal apparatus and accumulating the collected data, and computing a total of reductions in the weight of the food waste and a total of amounts of the consumed electric power in the entire system on the basis of the accumulated data on the reduction in the weight of the food waste and the accumulated data on the amount of the consumed electric power; and a public office server receiving the total of reductions in the weight of the food waste and the total of amounts of the consumed electric power in the entire system from the GL server.

The system may further include a manager terminal outputting the reduction in the weight of the food waste and the amount of the consumed electric power, the reduction and the amount being measured in the food waste disposal apparatus. In the system, the food waste disposal apparatus may transmit data on the reduction in the weight of the food waste and data on the amount of the consumed electric power to an Internet of Things platform (IoT (LTE-M, NB-IoT, LoRa, or SIGFOX) platform) through a wireless data network, the reduction and the amount being measured at the fixed time intervals, and the GL server may receive the data of the Internet of Things platform ((IoT (LTE-M, NB-IoT, LoRa, or SIGFOX) platform) and may accumulate the measured reductions in the weight of the food waste and the measured amounts of the consumed electric power.

In the system for measuring a reduction in a weight of food waste, which is described above, the food waste is decomposed in a short time and thus is converted into a recycled resource, such as compost. In this manner, the environment can be protected. In addition, according to the embodiment, the reduction in the weight of the food waste is automatically provided in a numerical manner, and thus reductions in carbon emissions can be integrally measured and be realized.

The present disclosure are limited to the effects described above. It should be understood that other effects can be derived from a detailed description of the present disclosure or from constituent elements of the present disclosure that are recited in the claims.

### BRIEF DESCRIPTION OF THE SEVERAL VIEWS OF THE DRAWINGS

The above and other objectives, features, and other advantages of the present disclosure will be more clearly understood from the following detailed description when taken in conjunction with the accompanying drawings, in which:

FIG. 1 is a view illustrating a configuration of a system for measuring a reduction in a weight of food waste according to an embodiment of the present disclosure;

FIG. 2 is a view illustrating a data processing configuration of a food waste disposal apparatus according to the embodiment;

FIG. 3 is a view illustrating a configuration of a food-waste decomposing module according to the embodiment;

FIG. 4 is a view illustrating a flow for data processing by the food waste disposal apparatus according to the embodiment; and

FIG. 5 is a view illustrating a signal flow in the system for measuring a reduction in a weight of food waste.

### DETAILED DESCRIPTION OF THE INVENTION

Advantages and features of the present disclosure and methods of achieving the advantages and the features will be apparent from embodiments that will be described in detail below with reference to the accompanying drawings. However, the present disclosure is not limited to the embodiments that will be described below and can be practiced in various different forms. The embodiments are only provided for full disclosure and to adequately teach a person of ordinary skill in the art to which the present disclosure pertains how to carry out the present disclosure. The scope of the present disclosure should be only defined in claims. The same reference numeral throughout the specification refers to the same constituent element.

Detailed descriptions of the embodiments of the present disclosure in terms of a notice function or configuration, when determined to unnecessarily make the nature and gist of the present disclosure unclear, will be omitted. The terms that will be used throughout the specification are ones defined by considering their functional meanings in the embodiments of the present disclosure. Therefore, these terms may be changed according to a user's intention, an operator's intention, the common practices in the art, or the like. Therefore, the terms used should be construed in light of the present specification.

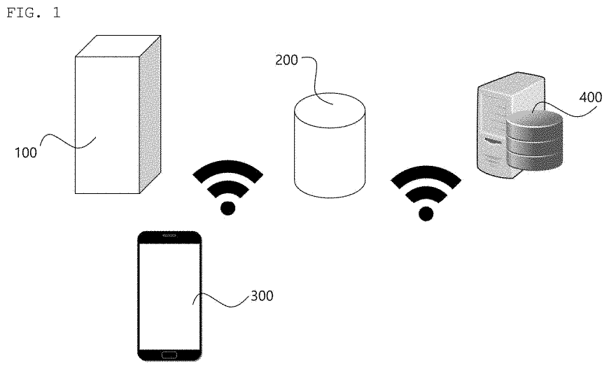

FIG. 1 is a view illustrating a configuration of a system for measuring a reduction in a weight of food waste according to an embodiment of the present disclosure.

With reference to FIG. 1, the system for measuring a reduction in a weight of food waste according to the embodiment of the present disclosure may be configured to include a fool waste disposal apparatus 100, an Internet of Things platform 200, a GL server 400, and a manager terminal 300.

A food waste disposal apparatus 100 measures a weight of food waste Introduced. Then, the food waste disposal apparatus 100 measures at fixed time intervals a reduction in the weight of the food waste and an amount of electric power consumed. For example, when a time interval for measurement is set to one hour, the food waste disposal apparatus 100 may measure the reduction in the weight of the food waste and the amount of the consumed electric power at time intervals of one hour. In the embodiment, weights that the food waste has before and after the food waste is decomposed, respectively, are measured. Then, a difference between a pre-decomposition weight of the food waste and a post-decomposition weight of the food waste may be computed as the reduction in the weight of the food waste.

The GL server 400 collects data on the reduction in the weight of the food waste and data on the amount of the consumed electric power from the food waste disposal apparatus 100 and accumulates the collected data. The GL server 400 computes a total of reductions in the weight of the food waste and a total of amounts of the consumed electric power in the entire system, on the basis of the accumulated data on the reduction in the weight of the food waste and the accumulated data on the amount of the consumed electric power.

A public office server receives from the GL server 400 data on the total of reductions in the weight of the food waste and data on the total of amounts of the consumed electric power in the entire system.

The manager terminal 300 outputs the reduction in the weight of the food waste and the amount of the consumed electric power that are measured in the food waste disposal apparatus 100. The manager terminal 300 according to the embodiment transmits to a communication module of the food waste disposal apparatus 100 a model name and a serial number that are included in a QR code of an apparatus for measuring a deduction in weight. The communication module transmits the model name and the serial number, the reduction in the weight and the amount of the consumed electric power, and the like to the Internet of Things platform 200 and the manager terminal 300. At least one manager terminal 300 here may be realized as a computer capable of making a connection to a remote server or terminal through a network. Examples of the computer here include a navigation device, a laptop computer, and a desktop computer on which a web browser is installed, and the like. At least one purchaser terminal 100 may be realized as a terminal capable of making a connection to the remote server or terminal through the network. Examples of at least one manager terminal 300 may include all types of handheld wireless communication devices with portability and mobility, such as navigation devices, and terminals, smartphones, smart pads, personal digital assistants (PDAs), and tablet PCs for Personal Communication System (PCS), Global System for Mobile communications (GSM), Personal Digital Cellular (PDC), Personal Handy-phone System (PHS), International Mobile Telecommunication (IMT)-2000, Code Division Multiple Access (CDMA)-2000, W-Code Division Multiple Access (W-CDMA), and Wireless Broadband Internet (Wibro).

The Internet of Things (IoT) platform 200 receives data on the reduction in the weight of the food waste that are measured at fixed time intervals and data on the amount of the consumed electric power that are measured at the fixed time intervals, from the food waste disposal apparatus 100 through a wireless data network. The GL server 400 receives the data of the Internet of Things (IoT) platform 200 and accumulates the measured reductions in the weight of the food waste and the measured amounts of the consumed electric power.

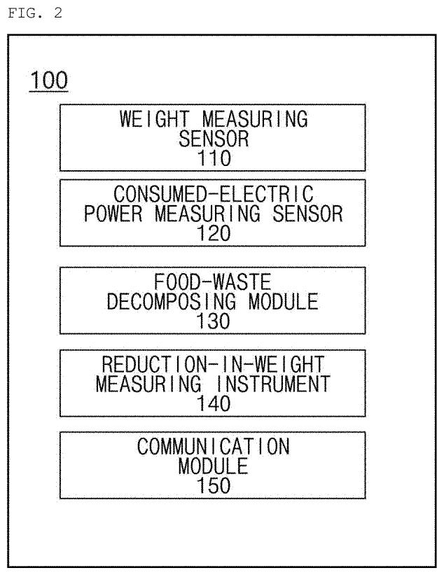

FIG. 2 is a view illustrating a data processing configuration of the food waste disposal apparatus 100 according to the embodiment.

With reference to FIG. 2, the food waste disposal apparatus 100 according to the embodiment may be configured to include a weight measuring sensor 110, a consumed-electric power measuring sensor 120, a food-waste decomposing module 130, a reduction-in-weight measuring instrument 140, and a communication module 150. The term “module” used through the present specification should be construed as including software, hardware, and a combination thereof, depending on the context in which this term is used. Examples of the software may include machine languages, firmware, embedded codes, and application software. Examples of hardware may include a circuit, a processor, a computer, an integrated circuit, an integrated circuit core, a sensor, a micro-electro-mechanical system (MEMS), a passive device, and a combination thereof.

The weight measuring sensor 110 measures a weight of food waste introduced. The consumed-electric power measuring sensor 120 measures an amount of electric power consumed in the food waste disposal apparatus 100. The food-waste decomposing module 130 decomposes food waste using microorganisms or the like. The reduction-in-weight measuring instrument 140 measures a reduction in a weight of the decomposed food waste. In the embodiment, the reduction-in-weight measuring instrument 140 may measure the weights that the food waste has before and after the food waste is decomposed, respectively, and may measure the difference between the pre-decomposition weight of the food waste and the post-decomposition weight of the food waste as the reduction in the weight of the food waste. In addition, in the embodiment, the reduction-in-weight measuring instrument 140 automatically transmits unique information of the reduction-in-weight measuring instrument 140 that includes the model name and the serial number, and the reduction in the weight and the amount of the consumed electric power, to the Internet of Things platform 200 and the manager terminal 300. In the embodiment, while maintaining a state of being connected to the Internet of Things (IoT) platform 200, the GL server 400 may integrally store the unique information of the reduction-in-weight measuring instrument 140 that includes the model name and the serial number, and the amount of the consumed electric power and may share the integrally stored data with a server in the Ministry of Environment of Republic of Korea and servers in other public offices of Republic of Korea. The communication module 150 performs wireless communication in compliance with Bluetooth (BLE) standards over the Internet of Things (Iot (LTE-M, NB-IoT, LoRa, or SIGFOX)).

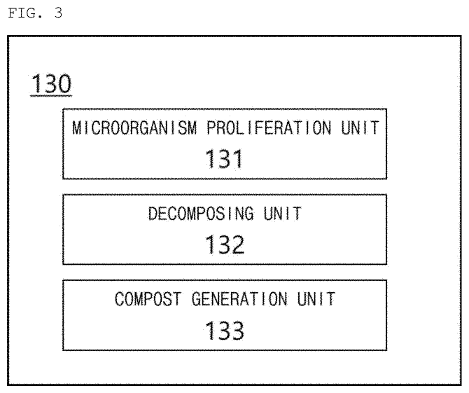

FIG. 3 is a view illustrating a configuration of the food-waste decomposing module 130 according to the embodiment.

With reference to FIG. 3, the food-waste decomposing module 130 according to the embodiment may be configured to include a microorganism proliferation unit 131, a decomposing unit 132, and a compost generation unit 133.

In the embodiment, the food-waste decomposing module 130 may be configured to include a system for disposing of food waste in an environment-friendly manner and an integrated system for converting a by-product of food waste into energy. The integrated system for converting a by-product of food waste into energy according to the embodiment may be configured to include a pellet forming apparatus and a dedicated pellet boiler. In the embodiment, the microorganism proliferation unit 131 may proliferate useful indigenous microorganisms that are highly heat-resistant and salt-resistant and may dispose of the food waste in an environment-friendly manner by utilizing the indigenous microorganisms. In the embodiment, the compost generation unit 133 may convert the by-product that results from decomposing the food waste, into biofuel (pellets) for resource recovery and thus may maximize the efficiency of using energy. In addition, the decomposing unit 132 derives useful indigenous microorganisms that decompose organic materials, such as food waste, and cultures the derived microorganisms in large quantities. The decomposing unit 132 may decompose and dispose of the food waste by utilizing the useful indigenous microorganisms. In the embodiment, the improved salt-resistance and heat-resistance of the useful indigenous microorganisms are 5% and 50° C., respectively, while the salt-resistance and heat-resistance of food-waste disposal microorganisms for use in the related art are 2% and 30° C., respectively. Therefore, the operational efficiency of the food-waste decomposing module 130 can be improved by two-fold or more. In addition, in the embodiment, the use of heat generated due to biological fermentation during decomposition of the food waste reduces energy necessary to operate the food waste disposal apparatus 100. In addition, according to the embodiment, a solid-biofuel (pellet) forming apparatus is provided. The solid-biofuel (pellet) forming apparatus may convert the by-product, generated when the useful indigenous microorganisms decomposes the food waste, into biofuel for resource recovery, and thus may maximize the efficiency of using energy. Accordingly, replacement of microorganisms to be imported from abroad with indigenous microorganisms can contribute to reduce royalties payable to a foreign company on the use of the imported microorganisms. In addition, the useful indigenous microorganisms can be secured as useful resources to be used in the food waste disposal apparatus 100 and the biofuel forming apparatus. The food waste can be decomposed in an environment-friendly manner by utilizing the useful indigenous microorganisms. In addition, in the embodiment, the microorganism proliferation unit 131 derives the useful microorganisms that decomposes the food waste and cultures the derived useful microorganisms in large quantities. Then, using the cultured useful microorganisms on the spot, the microorganism proliferation unit 131 may analyze group characteristics of the useful microorganisms when fermentation occurs. In addition, in the embodiment, the food-waste decomposing module 130 may in real time monitor a process of decomposing and dissolving the food waste and may automatically control this process.

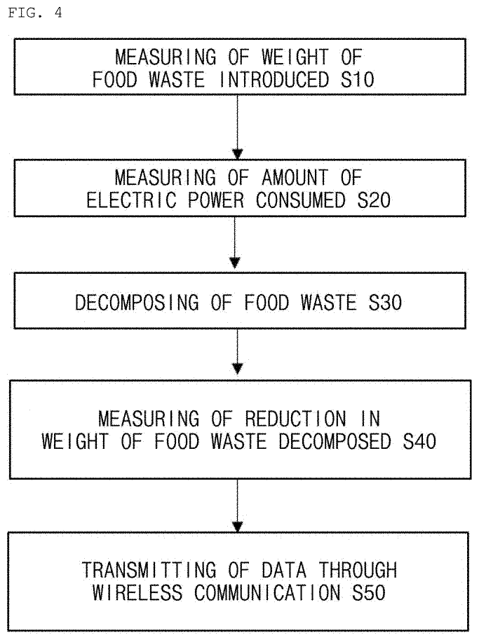

FIG. 4 is a view illustrating a flow for data processing by the food waste disposal apparatus 100 according to the embodiment.

With reference to FIG. 4, in Step S10, the weight measuring sensor 110 of the food waste disposal apparatus 100 according to the embodiment measures a weight of food waste introduced. In Step S20, the consumed-electric power measuring sensor 120 measures an amount of electric power consumed. In Step S30, the food-waste decomposing module 130 decomposes food waste. In Step S40, the reduction-in-weight measuring instrument 140 measures a reduction in a weight of the decomposed food waste. In the embodiment, weights that the food waste has before and after a process of decomposing the food waste is completed, respectively, may be computed. Then, a difference between the pre-decomposition weight and the post-decomposition weight may be computed as the reduction in the weight of the food waste. In Step S50, the communication module 150 transmits the reduction in the weight of the food waste and the amount of the consumed electric power to the GL server 400 or the Internet of Things platform 200.

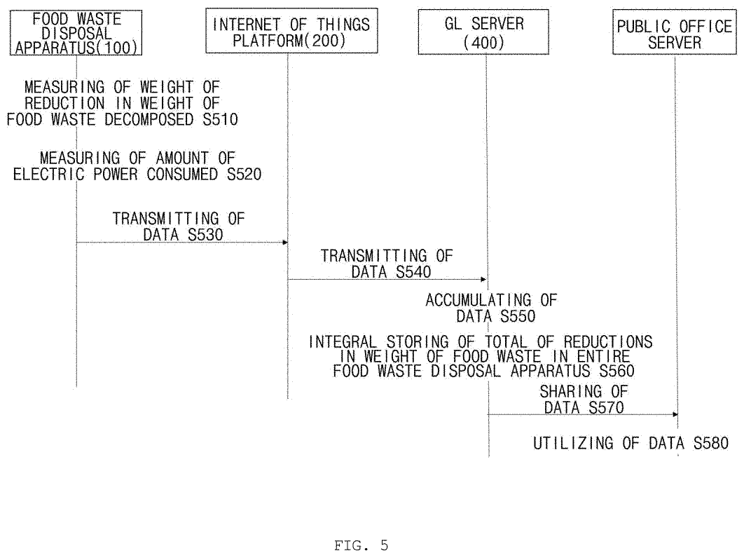

FIG. 5 is a view illustrating a signal flow in the system for measuring a reduction in a weight of food waste.

With reference to FIG. 5, the reduction in the weight of the food waste decomposed in the food waste disposal apparatus 100 is measured in Step S510, and the amount of the consumed electric power is measured in Step S520.

In Step S530, the food waste disposal apparatus 100 transmits data on the measured reduction in the weight of the food waste and data on the measured amount of the consumed electric power to the Internet of Things platform 200. In Step S540, the Internet of Things platform 200 transmits data on the measured reduction in the weight of the food waste and data on the measured amount of the consumed electric power to the GL server 400. In Step S550, the GL server 400 accumulates the received data. The GL server 400 integrally stores a total of reductions in the weight of the food waste in the entire food waste disposal apparatus 100 in Step S560, and shares the integrally stored data with the public office server in Step S570. In Step S580, the public office server may compute a reduction in carbon emissions through the received integrated data.

In the system for and the method of measuring a reduction in a weight of food waste, the weight of the food waste introduced into the food waste disposal apparatus 100 is measured, and the reduction in the weight of the food waste is measured at fixed time intervals after the weight of the food waste is measured. The data on the measured reduction in the weight of the food waste and the data on the measured amount of the consumed electric power are accumulated and processed, the total of reductions in the weight of the food waste in the entire food waste disposal apparatus is integrally stored, and the integrally stored data is shared with a server in the Ministry of Environment of Republic of Korea and servers in other public offices of Republic of Korea. In the system for and the method of measuring a reduction in a weight of food waste according to the embodiment, the food waste is decomposed in a short time and thus is converted into a recycled resource, such as compost. In this manner, the environment can be protected. In addition, according to the embodiment, the reduction in the weight of the food waste is automatically provided in a numerical manner, and thus a reduction in carbon emissions can be integrally measured and be realized.

The embodiment is disclosed only for illustrative purposes. A person of ordinary skill in the art can be enabled to practice the present disclosure in various forms without departing the nature and gist of the subject matter that is claimed in the claims. The scope of the present disclosure is not limited to the specific embodiment described above.

What is claimed is:

1. A system for measuring a reduction in a weight of food waste, the system comprising:
a food waste disposal apparatus measuring a weight of food waste introduced and measuring at fixed time intervals a reduction in the weight of the food waste and an amount of electric power consumed;
a GL server collecting data on the reduction in the weight of the food waste and data on the amount of the consumed electric power from the food waste disposal apparatus and accumulating the collected data, and computing a total of reductions in the weight of the food waste and a total of amounts of the consumed electric power in the entire system on the basis of the accumulated data on the reduction in the weight of the food waste and the accumulated data on the amount of the consumed electric power; and
a public office server receiving the total of reductions in the weight of the food waste and the total of amounts of the consumed electric power in the entire system from the GL server.

2. The system of claim 1, further comprising:
a manager terminal outputting the reduction in the weight of the food waste and the amount of the consumed electric power, the reduction and the amount being measured in the food waste disposal apparatus.

3. The system of claim 1, wherein the food waste disposal apparatus transmits data on the reduction in the weight of the food waste and data on the amount of the consumed electric power to an Internet of Things platform (IoT (LTE-M, NB-IoT, LoRa, or SIGFOX) platform) through a wireless data network, the reduction and the amount being measured at the fixed time intervals, and
wherein the GL server receives the data of the Internet of Things platform ((IoT (LTE-M, NB-IoT, LoRa, or SIGFOX) platform) and accumulates the measured reductions in the weight of the food waste and the measured amounts of the consumed electric power.

4. The system of claim 1, wherein the food waste disposal apparatus comprises:
a weight measuring sensor measuring a weight of food introduced;
a consumed-electric power measuring sensor measuring the amount of the consumed electric power;
a food waste decomposing module decomposing the food waste;
a reduction-in-weight measuring instrument measuring the reduction in the weight of the decomposed food waste; and
a communication module performing wireless communication in compliance with Bluetooth (BLE) standards over the Internet of Things (IoT(LTE-M, NB-IoT, LoRa, or SIGFOX))

5. The system of claim 2, wherein the manager terminal transmits to a communication module unique information including a model name and a serial number that are included in a QR code of a reduction-in-weight measuring instrument, and
wherein the communication module transmits the model name and the serial number, and the reduction in the weight of the food waste and the amount of the consumed electric power to an Internet of Things platform and the manager terminal.
